(19) United States
(12) Patent Application Publication
(10) Pub. No.: US 2023/0418987 A1
(43) Pub. Date: Dec. 28, 2023

(54) DETERMINATION OF OPTIMAL FOOTPRINT DIMENSIONS FOR ELEVATED STRUCTURE

(71) Applicant: DISH Wireless L.L.C., Englewood, CO (US)

(72) Inventors: Joseph William Oliver, JR., Denver, CO (US); Greg Ivey, Highlands Ranch, CO (US); Warren Newell Bloss, III, Castle Rock, CO (US)

(73) Assignee: DISH Wireless L.L.C., Englewood, CO (US)

(21) Appl. No.: 17/852,152

(22) Filed: Jun. 28, 2022

(51) Int. Cl. G06F 30/13

(52) U.S. Cl. CPC G06F 30/13

(57) ABSTRACT

A computer implemented method is provided for determining optimal footprint dimensions for an elevated structure. Information is received which indicates a platform height value of the elevated structure and is stored in a platform dimension data structure. A minimum adequate elevated platform area is determined based upon equipment dimension data and equipment clearance data stored in a platform equipment data structure and elevated platform dimension options stored in the platform dimension data structure. A given elevated platform configuration is selected based upon the determined minimum adequate elevated platform area. An access structure size is determined and selected based upon the platform height value stored in the platform dimension data structure. A total footprint area of the elevated structure is determined based upon the selected elevated platform configuration and the selected access structure size. Elevated platform specifications including the total footprint area are generated.

### TECHNICAL FIELD

The technology described herein relates to computerized determination of optimal footprint dimensions for elevated structures.

### BACKGROUND

Wireless telephone technology and related wireless data access for smart phone devices has become ubiquitous in most developed parts of the world. However, personal wireless devices of users must be physically located within antenna power range of transceiver antennas to access the telephone and data networks. To date, a massive network of antenna transceivers has been built with overlapping coverage ranges to provide seamless telephone and data access to users over large geographic areas. Transceiver antennas have been mounted on all manner of structures to provide service including on free standing antenna towers, building rooftops, building sidewalls, and high hills or mountains. In addition to the antennas, space is needed nearby for ancillary equipment such as power supply, control switches, and network interface connections to transfer the wireless signals to the wired network infrastructure (e.g., the Internet) and vice versa.

The advent of 5^{th} Generation (5G) wireless technology requires placement of even more transceiver antennas at closer spacing to achieve the promise of faster data transfer rates. Some desirable locations for antenna placement require elevation of the ancillary equipment above ground to ensure long-term viability of the equipment. For example, some desirable locations may be in flood plains or areas with high snow load. The ancillary equipment needs to be protected from being submerged underwater or buried under snow. The equipment also needs to be accessible in such weather-related conditions.

The information included in this Background section of the specification, including any references cited herein and any description or discussion thereof, is included for technical reference purposes only and is not to be regarded subject matter by which the scope of the invention as defined in the claims is to be bound.

### SUMMARY

In one example implementation, a computer implemented method for determining optimal footprint dimensions for an elevated structure is provided. receiving a platform height value for an elevated structure is received. Platform height information is retrieved from a platform dimension data structure. Elevated platform dimension options are retrieved from the platform dimension data structure. Equipment dimension data is retrieved from a platform equipment data structure. Equipment clearance data is retrieved from the platform equipment data structure. A minimum adequate elevated platform area is determined based upon the equipment dimension data and the equipment clearance data. A given elevated platform configuration is determined based upon the determined minimum adequate elevated platform area. Based upon the platform height value and the platform height information, an access structure size is determined. A total footprint area of the elevated structure is determined based upon the selected elevated platform configuration and the selected access structure size. Elevated platform specifications that include the total footprint area are generated.

In another example of the method, a maximum dimension limitation for the elevated structure is received. The given elevated platform configuration is further determined based upon the maximum dimension limitation.

In another example of the method, a selection of a staircase as an access structure option is received. A staircase size is determined based on the platform height value. The total footprint area is further determined based on the staircase size.

In another example of the method, a selection of a ladder as an access structure option is received. A ladder size is determined based on the platform height value. The given elevated platform configuration is further determined based on the required platform equipment selection.

In another example of the method, a selection of an equipment option priority is received. The given elevated platform configuration is further determined based upon the equipment option priority.

In another example of the method, a bill of materials is generated that identifies one or more components for building the elevated structure per the elevated platform specifications.

In another example of the method, the determination of the given elevated platform configuration further includes selection of a minimum standard platform configuration. The minimum standard platform configuration includes an area greater than the minimum adequate elevated platform area. Based upon the retrieved equipment dimension data and the retrieved equipment clearance data, required equipment is geometrically arranged within the minimum standard platform configuration. A determination of whether the geometric arrangement of the required equipment fits within the minimum standard platform configuration is made. If the required equipment does not fit, the required equipment is iteratively geometrically rearranged within the minimum standard platform configuration to determine whether any successive geometric rearrangement of the required equipment fits. If the required equipment fits, the minimum standard platform configuration as the given elevated platform configuration is selected.

In another example of the method, if no geometric rearrangement of the required equipment fits the minimum standard platform configuration after iterative geometric rearrangement of the required equipment, a next largest standard platform configuration is selected.

In another example implementation, a system including a computer processor and a non-transient storage device configured with non-transient, computer executable instructions. The instructions direct the computing processor to determine optimal footprint dimensions for an elevated structure by receiving a platform height value and storing the platform height value in a platform dimension data structure. The instructions further direct the computing processor to instantiate a platform area calculation module configured to iteratively determine a minimum adequate elevated platform area based on stored data stored in the platform dimension data structure including equipment dimension data, equipment clearance data, and elevated platform dimension options. The instructions further direct the computing processor to select a given elevated platform configuration based on the determined minimum adequate elevated platform area. The computing processor further instantiates an access structure selection module configured to determine an access structure size which depends upon the platform height value. The computing processor further instantiates a footprint calculation module configured to determine a total footprint area of the elevated structure which depends upon the given elevated platform configuration and the access structure size. The computing processor further instantiates a specification output module configured to output elevated platform specifications.

In another example of the system, the computing processor is further configured to receive user input information indicating a maximum dimension limitation of the elevated structure and store the maximum dimension limitation in the platform dimension data structure. The access structure selection module is further configured to select the given elevated platform configuration based on the maximum dimension limitation.

In another example of the system, the computing processor is further configured to receive user input information indicating a selection of a staircase as an access structure option. The access structure selection module is further configured to determine a staircase size which depends upon the platform height value stored in the platform dimension data structure. The footprint calculation module further configured to determine the total footprint area based upon the staircase size.

In another example of the system, the computing processor is further configured to receive user input information indicating a selection of a ladder as an access structure option. The access structure selection module is further configured to determine a ladder size which depends upon the platform height value stored in the platform dimension data structure. The footprint calculation module further configured to determine the total footprint area based upon the ladder size.

In another example of the system, the computing processor is further configured to receive a selection of required platform equipment. The given elevated platform configuration is further selected based upon the required platform equipment selection.

In another example of the system, the computing processor is further configured to receive a selection of an equipment option priority. The given elevated platform configuration is further selected based upon the equipment option priority.

In another example of the system, the computing processor further instantiates an a bill of materials module configured to generate a bill of materials, which lists components for building the elevated structure according to the elevated platform specifications, and output the bill of materials.

In another example of the system, the access structure selection module is further configured to select a minimum standard platform configuration with an area greater than the minimum adequate elevated platform area; geometrically arrange required equipment within the minimum standard platform configuration based on relevant equipment dimension data and relevant equipment clearance data for the required equipment; and determine whether the geometric arrangement of the required equipment fits within the minimum standard platform configuration. If the required equipment does not fit, the access structure selection module is further configured to iteratively geometrically rearrange the required equipment within the minimum standard platform configuration to determine whether any successive geometric rearrangement of the required equipment fits. If the required equipment fits, the access structure selection module is further configured to select the minimum standard platform configuration as the given elevated platform configuration.

In another example of the system, the access structure selection module is further configured to select a next largest standard platform configuration if, after iterative geometrically rearrangement of the required equipment, no geometric rearrangement of the required equipment fits the minimum standard platform configuration.

In another example implementation, a tangible processor-readable storage media may be embedded with instructions for executing a process on a computing device to determine optimal footprint dimensions for an elevated structure. The instructions may direct the computing device to receive user input information indicating a platform height value of the elevated structure. The instructions may further direct the computing device to store the platform height information in a platform dimension data structure. The instructions may direct the computing device to determine a minimum adequate elevated platform area based, at least in part, upon equipment dimension data and equipment clearance data stored in a platform equipment data structure and elevated platform dimension options stored in the platform dimension data structure. The instructions may direct the computing device to select a given elevated platform configuration based, at least in part, upon the determined minimum adequate elevated platform area. The instructions may direct the computing device to determine and select an access structure size based, at least in part, upon the platform height value stored in the platform dimension data structure. The instructions may direct the computing device to determine a total footprint area of the elevated structure based, at least in part, upon the selected elevated platform configuration and the selected access structure size. The instructions may further direct the computing device to output elevated platform specifications to a user including the total footprint area.

In another example, the one or more tangible processor-readable storage media may further include instructions directing the computing device to initially select a minimum standard platform configuration with an area that is greater than the minimum adequate elevated platform area. The instructions may further direct the computing device to geometrically arrange required equipment within the minimum standard platform configuration based, at least in part, upon relevant equipment dimension data and relevant equipment clearance data for the required equipment from the platform equipment data structure. The instructions may further direct the computing device to determine whether the geometric arrangement of the required equipment fits within the minimum standard platform configuration. The instructions may further direct the computing device to perform one or more of the following processes. If the required equipment does not fit, iteratively geometrically rearrange the required equipment within the minimum standard platform configuration to determine whether any successive geometric rearrangement of the required equipment fits. If the required equipment fits, select the minimum standard platform configuration as the given elevated platform configuration. If, after iteratively geometrically rearranging the required equipment, no geometric rearrangement of the required equipment fits the minimum standard platform configuration, selecting a next largest standard platform configuration.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. A more extensive presentation of features, details, utilities, and advantages of the present invention as defined in the claims is provided in the following written description of various embodiments and implementations and illustrated in the accompanying drawings.

### BRIEF DESCRIPTION OF THE DRAWINGS

The disclosure will be readily understood by the following detailed description in conjunction with the accompanying drawings, wherein like reference numerals designate like structural elements. It should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

FIG. 1 is a schematic of an elevated platform for supporting ancillary equipment for an adjacent wireless antenna tower.

FIG. 2 is a schematic, top plan view of the footprint of an elevated equipment platform with two stair steps and a related area calculation.

FIG. 3 is a schematic, top plan view of the footprint of an elevated equipment platform similar to the platform of FIG. 2 with nineteen stair steps and a related area calculation.

FIG. 4 is a schematic, top plan view of the footprint of an elevated equipment platform similar to the platform of FIG. 2 with a ladder configuration and a related area calculation.

FIG. 5 is a schematic, top plan view of the footprint of an elevated equipment platform with additional space for a generator and a related area calculation.

FIG. 6A is an example matrix for determination of equipment needs for an elevated equipment platform with equipment dimensions and related code clearance dimensions for determining required area of an elevated equipment platform.

FIG. 6B is an example matrix for determination of the total required area and footprint for an elevated equipment platform based upon selected equipment dimensions in the matrix of FIG. 6A.

FIGS. 7A and 7B are together an example flow diagram of a platform specification algorithm for determining total required area and footprint for an elevated equipment platform.

FIG. 8A is an example of a bill of materials for an elevated equipment platform generated by the algorithm of FIG. 7.

FIG. 8B is an example of a bill of materials for a staircase for an elevated equipment platform generated by the algorithm of FIG. 7.

FIG. 9 is a schematic diagram of an example computer system capable of implementing the processes for determining total required area and footprint for an elevated equipment platform.

### DETAILED DESCRIPTION

Base stations at wireless towers for transceiver antenna cells house or support multiple pieces of equipment needed to support the transceiver antennas. Such equipment may include radio transceivers, switches, network connection cabinets, control systems, power protection cabinets (PPC) for electrical hookup, on-site generators (e.g., to meet backup power requirements). As one example, fiber optic Network Interface Devices (NID) are designed to provide protection for fiber optic connectors and splices in indoor or outdoor environments. Each enclosure has a built in, swing-out mini splice tray and a bulkhead panel with industry standard subscriber connector (SC) footprint adapter ports. Often this equipment is housed within a small shed built on the ground adjacent to an antenna tower. In other installations, for example, when the antennas are mounted on the roof or exterior wall of a building, the related support equipment may be housed in unused mechanical areas of the building, for example, in a basement, or within a mechanical space dedicated to a floor.

However, some antenna tower locations are not able to take advantage of existing housing infrastructure. Also, some desirable antenna locations cannot support an equipment shed placed on grade. For example, if the antenna tower is to be located in a flood plain or in an area that is designated as a snow drift zone, above-grade equipment mounting solutions are required. Elevated platforms are excellent for use in flood plain areas or snow drift zone applications and are suitable for erection on either raw land or on rooftops, unless otherwise specified. In addition, if the housing enclosures for the base station equipment are rated for outdoor use, it may be more cost effective to merely mount the equipment on a platform rather than building a shed.

Current standard practice for design and build of elevated platforms for a wireless antenna tower base station can range from between 1-6 months. Typically, a site design manager identifies site requirements (e.g., generator needed/not needed). An architectural and engineering firm then may be retained to review site, identify height requirements, and perform necessary platform area calculations to provide platform construction specifications utilizing telecom provider-approved equipment and presently available options. A construction manager then reviews all the components specified for the project, creates a bill of materials (BOM), and orders the base station equipment and the components for the specified elevated platform. The construction manager may also use the specifications to seek any necessary construction permits. The site design manager may then use the construction specifications to negotiate the final lease with a property owner for the base station platform based upon the final calculated area.

Standard elevated platforms are designed to support the equipment of major telecom companies. These elevated platforms are available in various heights and are designed with grated decking to allow for rain and snow to pass through. Optional items include power and telecom racks, cable hangers, handrails, and ladders or stairs. Custom sizes and configurations ay be fabricated upon request. Elevated platforms are designed for rapid deployment and can be installed in a matter of hours instead of days once appropriate footings and pads are in place. Elevated platforms may also be shipped as component kits and in sections to mix and match needed sizes and components and for ease of handling during shipping and installation.

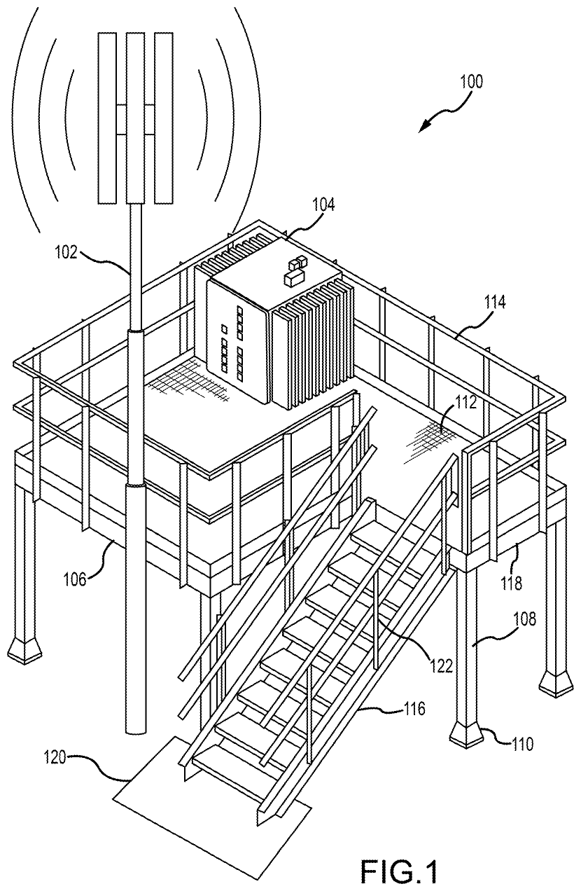

An example of an elevated platform 100 for housing base station equipment 104 of an adjacent antenna tower 102 is depicted in FIG. 1 for general reference. The elevated platform 100 includes a deck frame 106 supported by multiple posts, columns, or pillars 108 mounted on piers 110 or similar foundations. The deck frame 106 may be covered with steel decking 112 in an open grating pattern to allow for rain and snow to fall through. A safety railing system 114 may be mounted to and around the deck frame to prevent a worker from accidentally falling off the elevated platform 100. The safety railing system 114 may also serve as a mounting structure for one or more pieces of the base station equipment 104 installed on the elevated platform 100.

A staircase 116 is the preferred access structure for the elevated platform 100. An upper landing deck 118 at the top of the staircase 116 adjacent to the main deck frame 106 of the platform 100 is typically required by building code or Occupational Safety and Health Administration (OSHA) regulations. The base of the staircase 116 must be supported on a concrete landing 120 of required size based upon the width of the staircase 116. Additionally, handrails 122 are required on both sides of the staircase 116 per safety regulations.

The overall size in area, and the related footprint, of an elevated platform 100 depends upon a number of factors, including, for example, the required base station equipment and related dimensions of each piece of equipment; recommended and required clearances around each piece of equipment set by manufacturer recommendation and electrical, building, and safety codes; and the height of the elevated platform 100, which will dictate the length and related area of the staircase 116. For example, the National Electrical Code (NEC) requires: 1) at least a 3 ft (0.91 m) clearance in front of all electrical equipment; 2) a 30 in. (0.76 m) wide working space in front of electrical equipment operating at 600 V or less; and 3) minimum headroom clearance of 6 ft (1.83 m) or the height of the equipment, whichever is greater. In addition to the actual dimensions of a piece of equipment, the manufacturer may also specify clearances for optimal operation or safety. For example, manufacturer clearances for an electric generator may be 18 in. (0.46 m) on all sides for fire safety due to heat generation, plus clearance in front of the access panel of 3 ft (0.91 m) per NEC. Thus, the area of the elevated platform 100 must be selected to accommodate for both the dimensions of the base station equipment 104 as well as required clearances to ensure adequate space and spacing.

The height of the elevated platform 100 also impacts the final area of the elevated platform 100. The higher the elevated platform 100, the more steps are needed in the related staircase 116, resulting in a longer staircase 116 and a greater square area requirement. The typical rise to run ratio for a staircase is about 3:4 or about a 37-degree pitch. In addition, building code and OSHA requirements dictate the size of the concrete landing 120 at the base of the staircase 116, which is 3 ft (0.91 m) beyond the front edge of the staircase 116 and 6 in. wider than the staircase 116 on each side of the staircase 116.

The footprint differs from the minimum or base area calculations of the components once assembled and may require an increase in the overall area required for lease for an elevated platform 100 for base station equipment 104. The footprint accounts not only for the dimension of the deck frame 106, but also the appurtenances including the landing deck 118, the staircase 116, and the concrete landing 120 at the base of the staircase 116. As the height of the elevated platform 100 increases, the length of the staircase 116 increases, and thus the overall footprint expands, often beyond a simple rectangular box-shaped area.

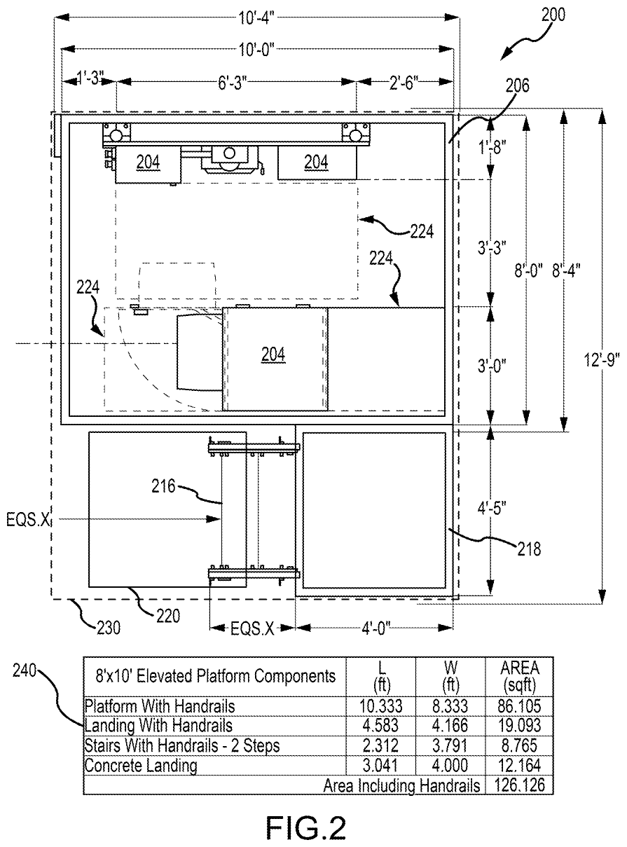

To better understand the implications of various elevated platform heights and base station equipment configurations, FIGS. 2-5 are provided for reference. FIG. 2 is a top plan view of an elevated platform configuration 200 including the deck frame 206, a landing deck 218, staircase 216, and a concrete landing 220. The height of this elevated platform configuration 200 is close to grade as the staircase only has two steps. Various pieces of equipment 104 are positioned in mounting locations on the deck frame 206. Various related equipment clearances 224 are also indicated by areas bounded by dashed lines in front of access locations for each piece of equipment 204. As is apparent, the equipment clearances 224 add a significant amount of required area to the minimum size of the deck frame 206, which is 8 ft (2.44 m) by 10 ft (3.05 m) (or 8.33 ft (2.54 m)×10.33 ft (3.15 m) with safety railing). However, in this example implementation, the staircase 216, landing deck 218, and concrete landing 220 add a minimal amount of area to the entire footprint 230 for the elevated platform configuration 200. In this embodiment, they do not extend beyond the width of the elevated platform configuration 200. The total area of the footprint 230 is indicated in the accompanying table 240 as 126.126 sq-ft (11.717 m²).

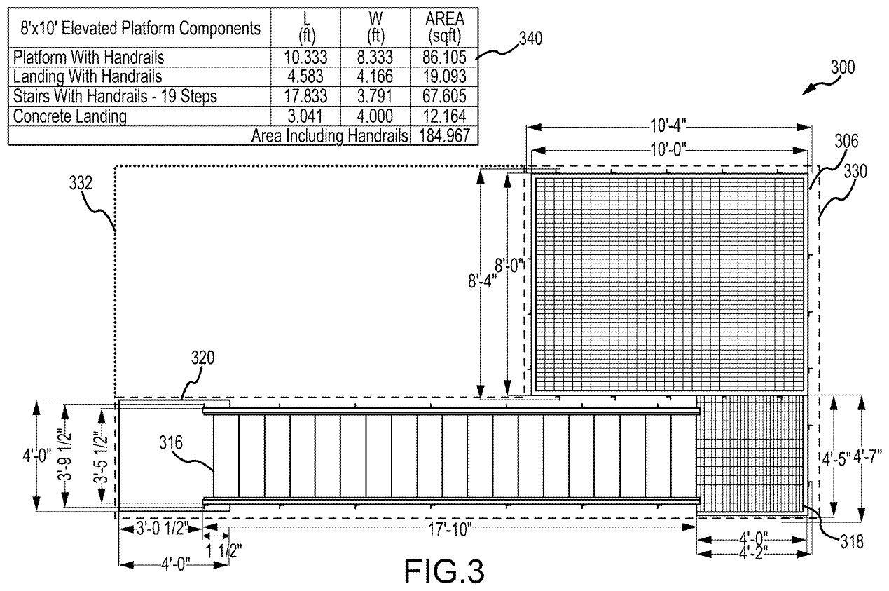

FIG. 3 is a top plan view of another elevated platform configuration 300 including the deck frame 306, a landing deck 318, staircase 316, and a concrete landing 320. The height of this elevated platform configuration 300 is far above grade as the staircase has nineteen steps. Based upon a typical staircase pitch of 37 degrees, the length of the staircase 216 indicated in the accompanying table 240 suggests a height of the deck frame at almost 11 ft (3.35 m). The base station equipment is not shown in FIG. 3, but for purposes of this illustration, the equipment is assumed to be similar to the equipment shown in FIG. 2 as the deck frame 306 is nominally 8 ft (2.44 m) by 10 ft (3.05 m). In this example implementation, the staircase 316, landing deck 318, and concrete landing 320 add a significant amount of area to the entire footprint 330 for the elevated platform configuration 300. In this embodiment, the staircase 316 extends well beyond the width of the elevated platform configuration 300. The total area of the footprint 330 is indicated in the accompanying table 340 as 184.967 sq-ft (17.184 m²), which is almost 60 sq-ft (5.57 m²) greater than the footprint 230 of the elevated platform configuration 200 of FIG. 2. In addition, the footprint for purposes of lease calculations may need to include an extended footprint area 332 because the area bounded on two sides by the staircase 316 and the deck frame 306 may be unusable or inaccessible for other purposes. The extended footprint area 332 would add approximately 122.867 sq-ft (11.415 m²) to the total area subject to a lease.

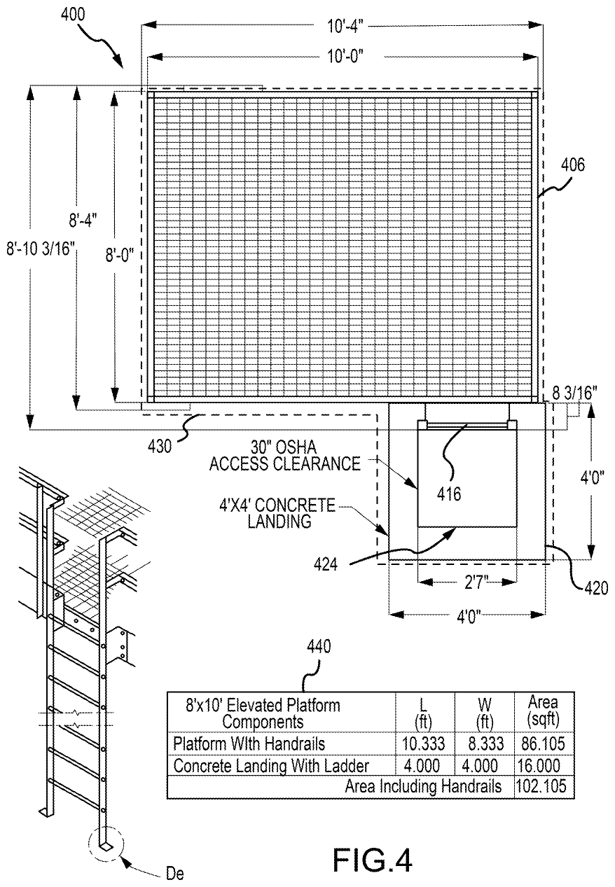

FIG. 4 is a top plan view of another elevated platform configuration 400 including the deck frame 406, a ladder 416, and a concrete landing 420. OSHA clearance for ladder is 30 in.×30 in. (0.762 m×0.762 m) and the concrete landing 420 needs to be another 10 in. wider than the required clearance. Due to site constraints (e.g., other encroaching structures), an alternate access structure, e.g., a ladder 416, may need to be used rather than a staircase. However, a ladder 416 is typically not preferrable and is generally to be avoided as a design option if at all possible. The base station equipment is not shown in FIG. 4, but for purposes of this illustration, the equipment is assumed to be similar to the equipment shown in FIG. 2 as the deck frame 406 is nominally 8 ft (2.44 m) by 10 ft (3.05 m). The height of this elevated platform configuration 400 can vary to any heigh above grade without changing the total area and footprint 430 because the pitch of the ladder remains vertical. The total area of the footprint 430 is indicated in the accompanying table 440 as 102.105 sq-ft (9.486 m²), which is slightly smaller than the area of the embodiment of FIG. 2. If a lease calculation is based upon the exact area used by the elevated platform configuration 400, this elevated platform configuration 400 may be less costly than the elevated platform configuration 200 of FIG. 2 if the cost per unit area is equivalent in the leases. In the case of FIG. 4, such may be an appropriate measure of footprint area if the use of the ladder was dictated by other encroaching structures.

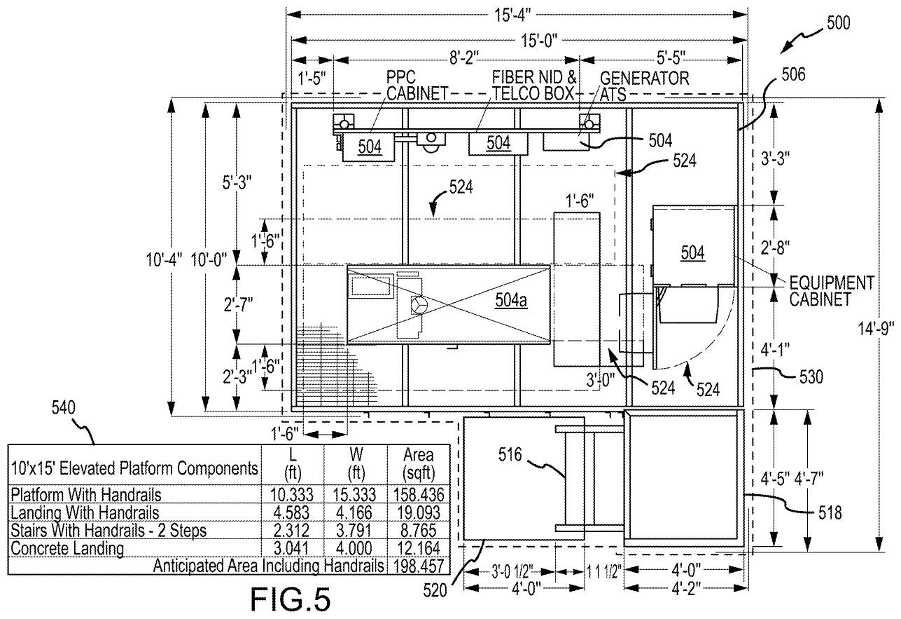

FIG. 5 is a top plan view of an elevated platform configuration 500 including the deck frame 506, a landing deck 518, staircase 516, and a concrete landing 520. The height of this elevated platform configuration 200 is close to grade as the staircase only has two steps. Various pieces of equipment 504 are positioned in mounting locations on the deck frame 506. In this example, a back-up power generator 504a and related components (e.g., an automatic transfer switch panel (ΔTS) to switch to and from generator power) are included as equipment. Thus, the deck frame 506 is a larger area than in previous embodiments to accommodate additional area requirements of the generator 504a. Various related equipment clearances 524 are also indicated by areas bounded by dashed lines in front of access locations for each piece of equipment 504, 504a. As is apparent, the equipment clearances 524 add a significant amount of required area to the minimum size of the deck frame 506, which is 10 ft (2.44 m) by 15 ft (3.05 m) (or 10.33 ft (3.15 m)×15.33 ft (4.67 m) with safety railing). However, in this example implementation, the staircase 516, landing deck 518, and concrete landing 520 add a minimal amount of area to the entire footprint 530 for the elevated platform configuration 500. In this embodiment, they do not extend beyond the width of the elevated platform configuration 500. The total area of the footprint 530 is indicated in the accompanying table 540 as 126.126 sq-ft (18.437 m²).

It may be appreciated that the total area of the footprint 530 of the elevated platform configuration 500 is only slightly larger than the total area of the footprint 330 of the elevated platform configuration 300, which has a deck frame 306 that is almost half the area of the platform deck 506 of the elevated platform configuration 500. This comparison is a clear illustration of the effect that the height of an elevated platform can have on the footprint due to the length and width of the associated staircase and upper and lower landings. When business goals are to be as cost-effective as possible, minimizing both material costs and lease costs may be important considerations. In addition, decreasing planning costs and time to build and active base stations may be desirable business objectives.

A computer implemented solution for determining and optimizing the footprint dimensions of an elevated platform for housing base station equipment, or for any other purpose is proposed to realize advantages of reduced planning and construction costs as well as decreasing the time needed to complete the build of an elevated platform structure. An algorithm underlying the computer implemented solution may be supported by multiple matrices identifying desired equipment, priorities, and limitations to output a smallest-footprint, cost-effective elevated platform solution within minutes rather than months. The computer implemented solution may further output a bill of materials for all components specified in the solution for ordering.

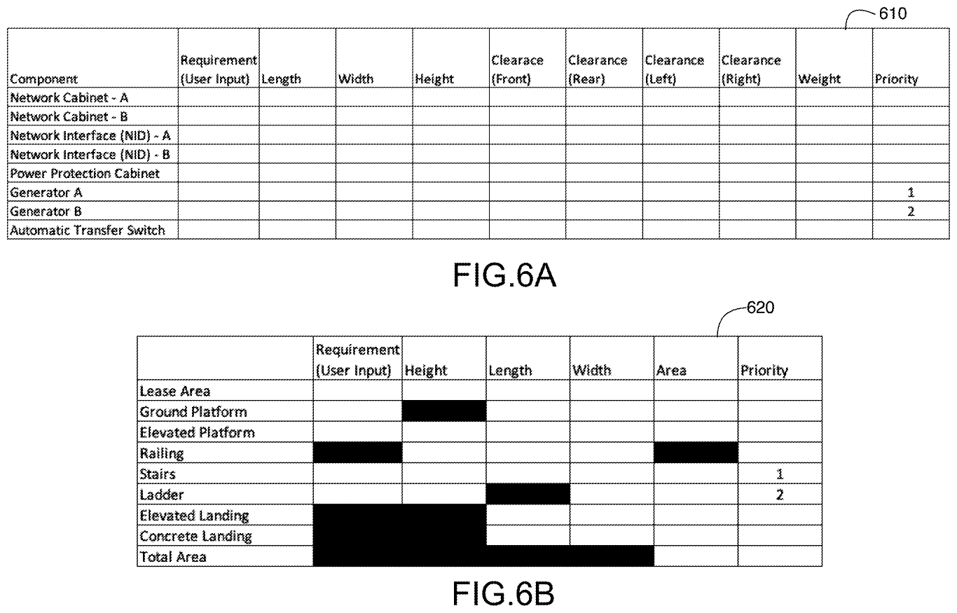

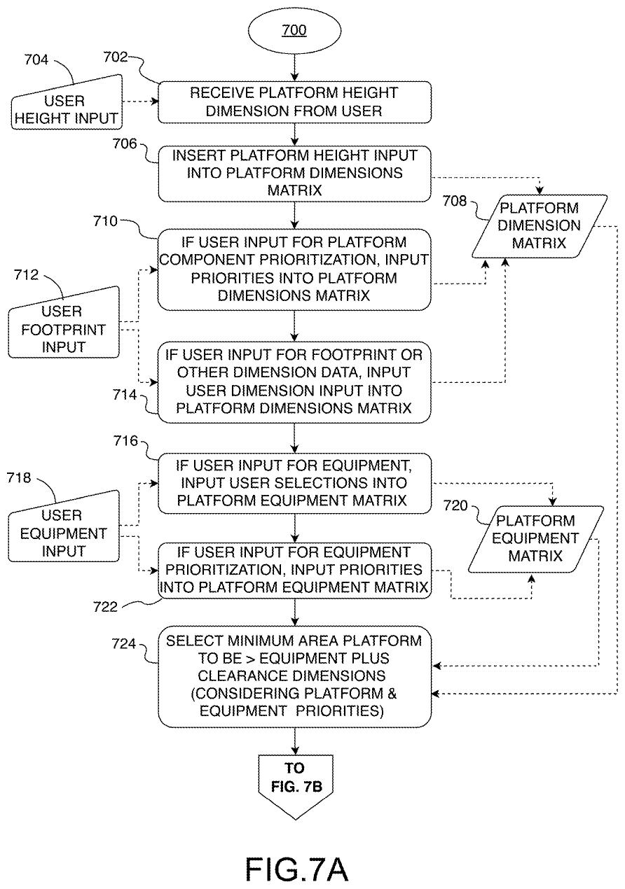

FIGS. 6A and 6B present two example matrices that may be used to provide information and identify priorities for consideration by a platform specification algorithm (as executed by a processor and further described below). For example, FIG. 6A presents a first matrix 610 the form of a selection table in which a site design manager may input equipment requirements for an elevated platform base station. The site design manager may indicate which pieces of equipment are required for the base station installation. For example, the site design manager may select from among a network cabinet, a network interface device, a power protection cabinet, a generator, and an automatic transfer switch as components for the base station. In some implementations, the site design manager may have the opportunity to select between multiple equipment models or manufacturers, for example, between network cabinets A and B or network interface devices A and B. In other implementations, there may not be a choice or certain pieces of equipment may be preselected by default as common to every installation.

The first matrix 610 may also provide an opportunity for the site design manager to prioritize between alternate options for equipment. For example, as indicated, if a generator is needed for a particular installation, the site design manager may indicate a preference between generator models or manufacturers (i.e., generator A vs. generator B) in a priority selection field. Alternatively, the priority field may indicate a default equipment priority (e.g., as established by the telecom provider) if not overridden by the site design manager.

The first matrix 610 may further include the dimensions of each piece of equipment available as well as corresponding clearances for the respective pieces of equipment according to manufacturer recommendations and government regulations. This dimensional information may or may not be presented to the site design manager, but regardless would be included in the matrix data for calculation of the minimum area required for a deck frame of an elevated platform to support the selected or required equipment.

An example of a second matrix 620 is presented in FIG. 6B. The second matrix 610 provides an opportunity for a site design manager to input specific dimensions of the elevated platform for consideration by the platform specification algorithm. The one component that the site design manager will need to input is the height of the elevated platform. Other measurements are optional. However, if the site design manager knows of certain constraints in advance, e.g., the width of the area is limited to a certain measurement or lease cost considerations dictate that the overall footprint cannot exceed a certain area or the lease budget will be exceeded, such measurements or values can be entered into the matrix manually by the site design manager and will be given priority with respect to other factors. In addition, certain options may be afforded priority, for example, staircase vs. ladder. The default priority may be set to staircase for safety considerations. However, if the site design manager determines that a ladder needs to be used on a certain project, the priority may be changed to place ladder first or to discount the option of a staircase entirely. Again, all of the dimensional information calculated within the matrix need not be presented to the site design manager or other user, but rather only fields receptive to input may be provided in an appropriate user interface presentation.

Other data matrices may be provided for use by the platform specification algorithm for consideration of other parameters. For example, If the necessary height of the elevated platform exceeds a certain level, OSHA requirements dictate the insertion of an intermediate deck landing, thus extending the length of the staircase or providing an opportunity to turn the staircase in an opposing or perpendicular direction. By including an intermediate deck landing, the footprint of the staircase could be contained in a smaller area and the overall footprint of the elevated platform could be reduced. Such an additional matrix of alternative staircase and landing deck options could be provided for consideration to minimize the footprint of the elevated platform if such is a priority consideration.

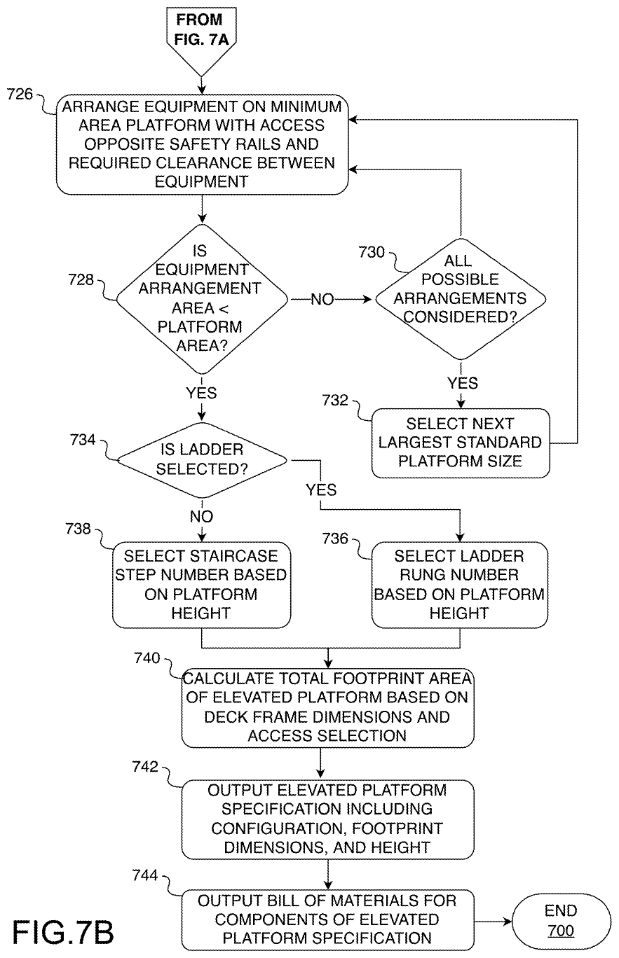

An example implementation of a platform specification algorithm 700 for determining optimal footprint dimensions of an elevated platform for base station equipment for a wireless antenna tower is depicted in the flow diagram spanning FIGS. 7A and 7B. The platform specification algorithm 700 may begin, e.g., through a user interface module configured for data collection tasks, in operation 702 with the receipt of a platform height dimension from a user via manual input 704 by a user through a user interface presented as an ancillary function of the platform specification algorithm 700. The platform height input from the user is then stored in a platform dimension matrix 708, or other appropriate data structure, as indicated in operation 706. If user input 712 for platform component prioritization, for example, a ladder vs. a staircase is received, such priorities are also stored in the platform dimensions matrix 708 as indicated in operation 710. Similarly, if user input 712 is received for a maximum footprint value or a maximum value for another dimension, e.g., due to site limitations or constrictions, these dimensional values are further stored in the platform dimensions matrix 708 as indicated in operation 714.

Next, the platform specification algorithm 700 considers whether additional user input 718 related to equipment selections is received. If so, such user selections are stored within a platform equipment matrix 720, or other appropriate data structure, as indicated in operation 716. Further, if user input 718 regarding equipment prioritization is received, such equipment priorities are also stored in the platform equipment matrix 720 as indicated in operation 722.

Once all user input data is received, the platform specification algorithm 700 undertakes an iterative process for determining an appropriate size for the elevated platform, e.g., using a platform area calculation module configured for the task. As indicated in operation 724, platform specification algorithm 700 first selects minimum area platform to be the smallest standard platform that has an area greater than the combined areas of the selected equipment plus the clearance dimensions for each piece of selected equipment. This determination takes into consideration any platform dimension requirements entered by the user as well as particular equipment selections when calculating dimensions. The platform specification algorithm 700 next geometrically arranges equipment on the selected minimum area platform to determine whether the equipment, including required clearances, will actually fit on the platform as indicated in operation 726. In performing this geometric arrangement, the platform specification algorithm 700 may arrange the equipment in orientations with access panels positioned opposite safety rails, i.e., the back sides of pieces of equipment are placed against the perimeter of the elevated platform. Decision operation 728 determines whether in the selected arrangement and orientation, the total area bounding the equipment, including the required clearances between pieces of equipment, is less than the area of the selected minimum area platform. If not, the platform specification algorithm 700 considers whether all possible configurations of the selected equipment have been consider as indicated in decision operation 730. If not, the process returns to operation 726 to attempt an alternative arrangement of the equipment and consider whether any alternative arrangements will fit within the area of the selected minimum area platform. If the process iterates through all possible combinations of equipment positions and arrangements within the area of the minimum area platform and no configuration is adequate, the platform specification algorithm 700 selects the next largest standard platform size as indicated in operation 732 and the process returns to operation 726 to attempt alternative arrangements of the equipment on within the area of the next largest platform size.

Once an acceptable geometric configuration of the selected equipment on an appropriate platform size is determined in decision operation 728, the platform specification algorithm 700 next considers the selected access structure for the elevated platform, i.e., whether the user has prioritized selection of a ladder for platform access instead of a default staircase selection as indicated in operation 734. If a ladder has been chosen as the access structure, a process, e.g., within a ladder access structure selection module configured for the task, selects an appropriate ladder height or number of rungs based upon the user selected height of the platform in the platform dimensions matrix 708 as indicated in operation 736. Alternatively, if the default staircase is selected as the access structure for reaching the elevated platform, an alternate process, e.g., within a staircase access structure selection module configured for the task, selects an appropriate staircase height or number of steps based upon the user selected height of the platform in the platform dimensions matrix 708 as indicated in operation 738. In either case, once appropriate staircase or ladder configurations have been determined, platform specification algorithm 700 can now calculate the total footprint area of the elevated platform, e.g., within a discrete footprint calculation module configured for the task, based on deck frame dimensions and access selection (i.e., whether a staircase or ladder is used to access the platform) as indicated in operation 740.

Once the final dimensional calculations are made, the platform specification algorithm 700, e.g., within a specification output module configured for the task, may output specifications for an appropriate output elevated platform for the site, including configuration, footprint dimensions, and height. The specification output module may access relevant dimension data from the platform dimension matrix and relevant equipment data from the platform equipment matrix, as well as additional component information stored in similar related data structures. The platform specification algorithm 700 may further generate and output one or more bills of materials based upon the specifications, e.g., within a bill of materials module configured for the task. The bills of materials may be comprehensive listings of component parts needed to erect the specified elevated platform including, for example, part numbers, quantities, descriptions, measurements, weights, vendors or suppliers, necessary hardware, and other information. A construction manager can easily use the bills of materials to place orders for the materials needed to erect the specified elevated platform.

The platform specification algorithm 700 thus renders specifications with dimensional information for an elevated platform and a related materials list within minutes rather than months. Immediate knowledge of the footprint area allows the site design manager to determine accurate site lease costs based upon unit area costs and more quickly complete lease negotiations with the property owner. The specifications may be generated with minimal information, for example, equipment requirements and height. Alternatively, if the site design manager has a site with area constraints, the platform specification algorithm 700 can quickly provide a design for an elevated platform configuration within the maximum footprint area or meeting the limiting dimension (e.g., platform length or width or staircase length) in moments rather than waiting for an architect to manually iterate through multiple design options.

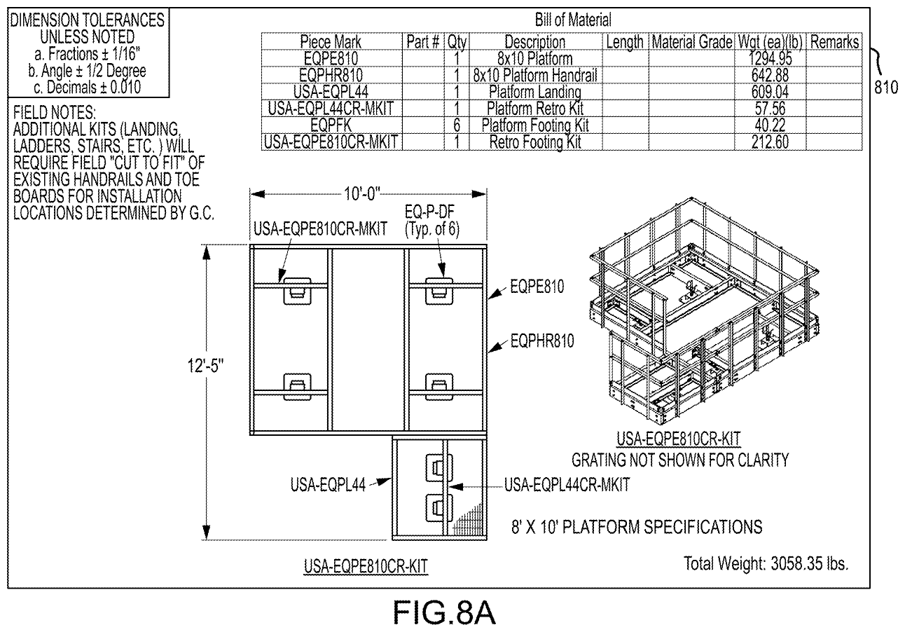

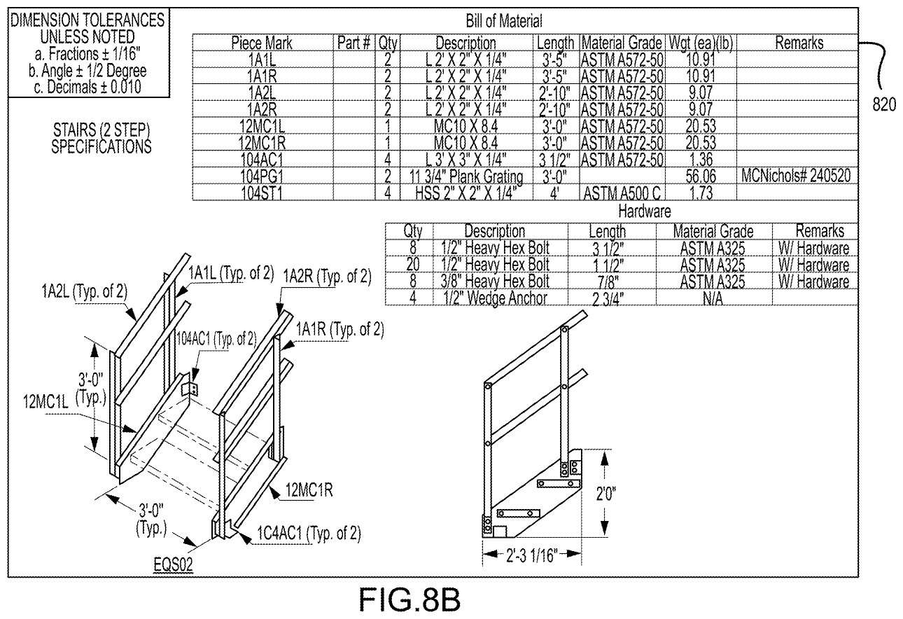

FIGS. 8A and 8B are examples of bills of materials that may be output by the platform specification algorithm in addition to the determined elevated platform configuration, including height and footprint dimensions. FIG. 8A is an example of a first bill of materials 810 for an 8 ft (2.44 m)×10 ft (3.05 m) elevated platform with a deck landing and safety rails. The first bill of materials 810 may include a listing of component parts to order including part numbers, quantities, descriptions, measurements, weights, supplier, and other information. This information allows a construction manager to easily place orders for the required components. The first bill of materials 810 may also include schematic diagrams of the component parts and general dimensions to provide ease of understanding of the components to be ordered and allow for a quality check that the output is accurate. In some implementations, as indicated in the first bill of materials 810, some of the components may themselves be kits for use with any platform design. Information about the components within these kits may be further output of the platform specification algorithm on additional bills of materials.

FIG. 8B is an example of a second bill of materials 820 for a staircase of two steps in height that may be used in conjunction with the elevated platform, deck landing, and safety rails of the first bill of materials 810. The second bill of materials 820 may include a listing of component parts to order including part numbers, quantities, descriptions, measurements, weights, related hardware, suppliers, and other information. This information allows a construction manager to easily place orders for the required components. The second bill of materials 820 may also include schematic diagrams of the staircase and general dimensions to provide ease of understanding of the components to be ordered and allow for a quality check that the output is accurate.

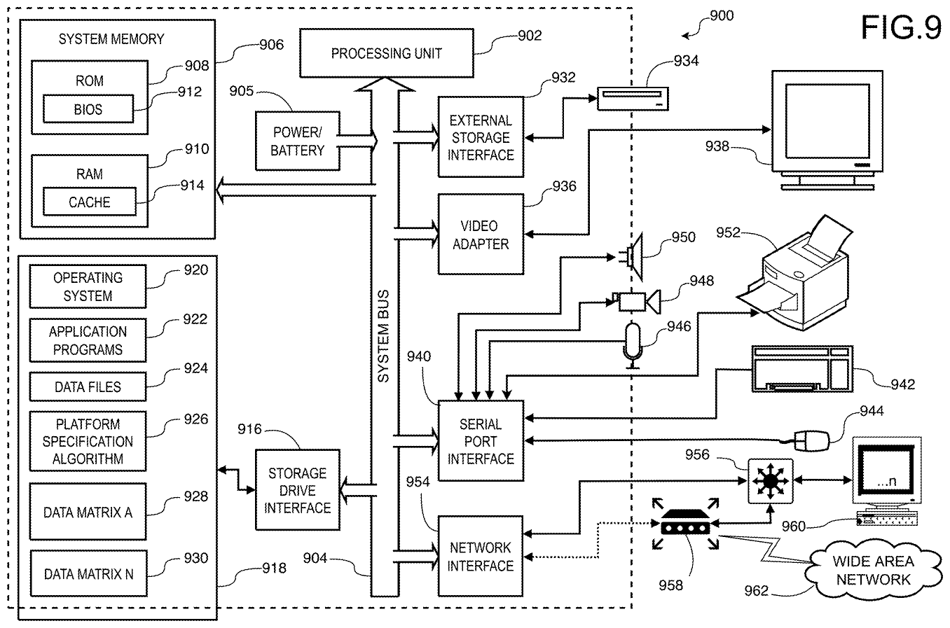

An exemplary computer system 900 implementing the processes performed thereby as described above is depicted in FIG. 9. The computer system 900 may be special purpose computer device, or it may be one or more of a personal computer (PC), a workstation, a notebook or portable computer, a tablet computer, a smart phone device, a video gaming device, or other computer device, with internal processing and memory components as well as interface components for connection with external input, output, storage, network, and other types of peripheral devices, particularly configured to perform the functions described herein. Alternatively, the computer system 900, for example, may be in the form of any of a server, a virtual machine instantiated on a server, a distributed computer, an Internet appliance, or other computer devices, or combinations thereof. Internal components of the computer system 900 in FIG. 9 are shown within the dashed line and external components are shown outside of the dashed line. Components that may be internal or external are shown straddling the dashed line.

In any embodiment described herein, the computer system 900 includes a processing unit (or processor) 902 and a system memory 906 connected by a system bus 904 that also operatively couples various system components. There may be one or more processors 902, e.g., a single central processing unit (CPU), or a plurality of processing units, commonly referred to as a parallel processing environment (for example, a dual-core, quad-core, or other multi-core processing device). The system bus 904 may be any of several types of bus structures including a memory bus or memory controller, a peripheral bus, a switched-fabric, point-to-point connection, and a local bus using any of a variety of bus architectures. The computer system 900 may include a power source 905, e.g., either or both an electrical port for connecting to an AC/DC inverter for constant power or a battery for working without a connected power source or for provision of backup power in a case of general or local power outage or emergency.

The system memory 906 includes read only memory (ROM) 908 and random access memory (RAM) 910. A basic input/output system (BIOS) 912, containing the basic routines that help to transfer information between elements within the computer system 900, such as during start-up, is stored in ROM 908. A cache 914 may be set aside in RAM 910 to provide a high-speed memory store for frequently accessed data.

A storage drive interface 916 may be connected with the system bus 904 to provide read and write access to a data storage drive 918, e.g., a magnetic hard disk drive or a solid state drive for nonvolatile storage of applications, files, and data. A number of program modules and other data may be stored on the storage drive 918, including an operating system 920, one or more application programs 922, and related data files 924. In particular, a platform specification algorithm 926 for calculating an optimal design and footprint for an elevated platform may be stored on the data storage drive 918. In addition, a number of data matrices 928, 930 may be stored with related data, e.g., equipment selections and dimensions and platform dimensions, in the data storage drive 918. Note that the data storage drive 918 may be either an internal component or an external component of the computer system 900 as indicated by the storage drive 918 straddling the dashed line in FIG. 9.

In some configurations, there may be both an internal and an external storage drive. For example, one or more external storage drives 934 may be connected with the system bus 904 via an external storage interface 932 to provide read and write access to the external storage drive 934 initiated by other components or applications within the computer system 900. In some embodiments, external storage drives may also be connected to the system bus 904 via a serial port interface 940 further described below. Exemplary external storage drives 934 may include a magnetic disk drive for reading from or writing to a removable magnetic disk, tape, or other magnetic media, and/or an optical disk drive for reading from or writing to a removable optical disk such as a CD-ROM, a DVD, or other optical media. The external storage drive 934 and any associated removable computer-readable media may be used to provide nonvolatile storage of computer-readable instructions, data structures, program modules, and other data for the computer system 900.

The computer system 900 may include a display device 938, e.g., a monitor, a television, or a projector, or other type of presentation device connected to the system bus 904 via an interface, such as a video adapter 936 or a video card. The computer system 900 may also include other peripheral input and output devices, which are often connected to the processor 902 and memory 906 through the serial port interface 940 that is coupled to the system bus 906. Input and output devices may also or alternately be connected to the system bus 904 by other interfaces, for example, a universal serial bus (USB), an IEEE 1394 interface (“Firewire”), a parallel port, or a game port, or wirelessly e.g., using a Bluetooth® connection interfacing with the serial port 940 or system bus 904. A user may enter commands and information into the computer system 900 through various input devices including, for example, a keyboard 942 and pointing device 944, for example, a computer mouse. Other input devices may include, for example, a microphone 946 and a digital video camera 948, or (not shown) a digital camera, a joystick, a game pad, a tablet, a touch screen device, a satellite dish, a scanner, or a facsimile machine.

Output devices may include one or more loudspeakers 950 for presenting the audio performance of the sender. Audio devices, for example, loudspeakers 950 or a microphone 946, may alternatively be connected to the system bus 904 through an audio card or other audio interface (not shown). Other output devices may include, for example, a printer 952, or (not shown) a plotter, a photocopier, a photo printer, a facsimile machine, and a press. In some implementations, several of these input and output devices may be combined into single devices, for example, a printer/scanner/fax/photocopier. It should also be appreciated that other types of computer-readable media and associated drives for storing data, for example, magnetic disks or flash memory drives, may be accessed by the computer system 900 via the serial port interface 940 (e.g., USB) or similar port interface.

The computer system 900 may operate in a networked environment using logical connections through a network interface 954 coupled with the system bus 904 to communicate with one or more remote devices. The logical connections depicted in FIG. 9 include a local-area network (LAN) 956 and a wide-area network (WAN) 962. Such networking environments are commonplace in home networks, office networks, enterprise-wide computer networks, and intranets. These logical connections may be achieved by a network access device 958 coupled to or integral with the computer system 900. As depicted in FIG. 9, the network access device 956 may operate as both a wireless router for directing traffic on the LAN 958 or may connect with a switch or hub (the physical structure of the LAN 956), either wired or wireless, internal or external, to connect with remote devices, e.g., a remote computer 958, similarly connected on the LAN 958. The remote computer 958 may be another personal computer, a server, a client, a peer device, or other common network node, and typically includes many or all of the elements described above relative to the computer system 900.

To connect the computer system 900 with a WAN 962, the network access device typically includes a modem for establishing communications over the WAN 962. However, in some embodiments, the modem for external network connections and the router for local network connections may be separate components. Most often the WAN 962 may be the Internet. However, in some instances the WAN 962 may be a large private network spread among multiple locations, or a virtual private network (VPN). The modem component of the network access device 956 may be a telephone modem, a high-speed modem (e.g., a digital subscriber line (DSL) modem), a cable modem, or similar type of communications device. The network access device 956 with modem is connected to the system bus 904 via the network interface 954. In alternate embodiments the network access device 956 may be connected via the serial port interface 944. It should be appreciated that the network connections shown are exemplary and other means of and communications devices for establishing a network communications link between the computer system 900 and other devices or networks may be used.

The terms “module,” “program,” and “engine” may be used to describe one or more of a hardware component, a software process, or a combination of both, that implement logical operations and/or algorithms to perform a particular function. It will be understood that different modules, programs, and/or engines refer to discrete components of software code that each may perform independent subroutines, tasks, or calculations by implementing one or more algorithms and together perform the functions of the larger application. Modules, programs, or engines may be called upon instantiated by one or more applications, services, code blocks, objects, libraries, routines, scripts, application program interfaces (API), functions, etc. When incorporating software, the modules, programs, and engines may encompass individual or groups of executable files, data files, libraries, drivers, scripts, database records, etc. The logical operations may be implemented as a sequence of processor-implemented steps executing in one or more computer systems and as interconnected machine or circuit modules within one or more computer systems. Likewise, the descriptions of various component modules may be provided in terms of operations executed or effected by the modules. The resulting implementation is a matter of choice, dependent on the performance requirements of the underlying system implementing the described technology. Furthermore, logical operations may be performed in any order, unless explicitly claimed otherwise or a specific order is inherently necessitated by the claim language.

In some implementations, articles of manufacture are provided as computer program products that cause the instantiation of operations on a computer system to implement the procedural operations. One implementation of a computer program product provides a non-transitory computer program storage medium readable by a computer system and encoding a computer program. It should further be understood that the described technology may be employed in special purpose devices independent of a personal computer.

All directional references (e.g., proximal, distal, upper, lower, upward, downward, left, right, lateral, longitudinal, front, back, top, bottom, above, below, vertical, horizontal, radial, axial, clockwise, and counterclockwise) are only used for identification purposes to aid the reader's understanding of the structures disclosed herein, and do not create limitations, particularly as to the position, orientation, or use of such structures. Connection references (e.g., attached, coupled, connected, and joined) are to be construed broadly and may include intermediate members between a collection of elements and relative movement between elements unless otherwise indicated. As such, connection references do not necessarily infer that two elements are directly connected and in fixed relation to each other. The exemplary drawings are for purposes of illustration only and the dimensions, positions, order and relative sizes reflected in the drawings attached hereto may vary.

The above specification, examples and data provide a complete description of the structure and use of exemplary embodiments of the invention as defined in the claims. Although various embodiments of the claimed invention have been described above with a certain degree of particularity, or with reference to one or more individual embodiments, other embodiments using different combinations of elements and structures disclosed herein are contemplated, as other iterations can be determined through ordinary skill based upon the teachings of the present disclosure. It is intended that all matter contained in the above description and shown in the accompanying drawings shall be interpreted as illustrative only of particular embodiments and not limiting. Changes in detail or structure may be made without departing from the basic elements of the invention as defined in the following claims.

What is claimed is:

1. A computer implemented method comprising:
receiving a platform height value for an elevated structure;
retrieving platform height information from a platform dimension data structure;
retrieving elevated platform dimension options from the platform dimension data structure;
retrieving equipment dimension data from a platform equipment data structure;
retrieving equipment clearance data from the platform equipment data structure;
first determining a minimum adequate elevated platform area based upon the equipment dimension data and the equipment clearance data second determining a given elevated platform configuration based upon the determined minimum adequate elevated platform area;
third determining, based upon the platform height value and the platform height information, an access structure size;
fourth determining a total footprint area of the elevated structure based upon the selected elevated platform configuration and the selected access structure size; and
generating elevated platform specifications that include the total footprint area.

2. The computer implemented method of claim 1 further comprising:
receiving a maximum dimension limitation for the elevated structure; and
wherein the second determining of the given elevated platform configuration is further based upon the maximum dimension limitation.

3. The computer implemented method of claim 1, further comprising:
receiving a selection of a staircase as an access structure option;
fifth determining a staircase size based on the platform height value; and
wherein the fourth determining of the total footprint area is further based upon the staircase size.

4. The computer implemented method of claim 1, further comprising:
receiving a selection of a ladder as an access structure option;
fifth determining a ladder size based on the platform height value; and
wherein the fourth determining of the total footprint area is further based upon the ladder size.

5. The computer implemented method of claim 1, further comprising:
receiving a selection of required platform equipment; and
wherein the second determining of the given elevated platform configuration is further based upon the required platform equipment selection.

6. The computer implemented method of claim 1, further comprising:
receiving a selection of an equipment option priority; and
wherein the second determining of the given elevated platform configuration is further based upon the equipment option priority.

7. The computer implemented method of claim 1, further comprising:
generating a bill of materials;
wherein the bill of materials identifies one or more components for building the elevated structure per the elevated platform specifications.

8. The computer implemented method of claim 1,
wherein the second determining of the given elevated platform configuration further comprises:
selecting a minimum standard platform configuration;
wherein the minimum standard platform configuration includes an area greater than the minimum adequate elevated platform area;
geometrically arranging, based upon the retrieved equipment dimension data and the retrieved equipment clearance data, required equipment within the minimum standard platform configuration;
determining whether the geometric arrangement of the required equipment fits within the minimum standard platform configuration;
if the required equipment does not fit,
iteratively geometrically rearranging the required equipment within the minimum standard platform configuration to determine whether any successive geometric rearrangement of the required equipment fits; and
if the required equipment fits,
selecting the minimum standard platform configuration as the given elevated platform configuration.

9. The computer implemented method claim 8,
wherein if after iteratively geometrically rearranging the required equipment no geometric rearrangement of the required equipment fits the minimum standard platform configuration, the method further comprises:
selecting a next largest standard platform configuration.

10. A system comprising:
a computing processor;
a non-transient storage device configured with non-transient, computer executable instructions for directing the computing processor to determine optimal footprint dimensions for an elevated structure including:
receiving a platform height value; and
storing the platform height value in a platform dimension data structure;
instantiate a platform area calculation module configured to perform operations including:
iteratively determining a minimum adequate elevated platform area based on stored data including:
equipment dimension data;
equipment clearance data; and
elevated platform dimension options;
wherein the stored data is stored in the platform dimension data structure; and
selecting a given elevated platform configuration based on the determined minimum adequate elevated platform area;
an access structure selection module configured to perform operations including:
determining an access structure size; and
wherein the access structure size depends upon the platform height value;
a footprint calculation module configured to perform operations including:
determining a total footprint area of the elevated structure;
wherein the total footprint area depends upon the given elevated platform configuration and the access structure size; and
a specification output module configured to perform operations including:
outputting elevated platform specifications.

11. The system of claim 10,
wherein the computer executable instructions further comprise:
receiving user input information indicating a maximum dimension limitation of the elevated structure; and
storing the maximum dimension limitation in the platform dimension data structure; and
wherein the access structure selection module is further configured to perform operations including:
selecting the given elevated platform configuration based on the maximum dimension limitation.

12. The system of claim 10,
wherein the computer executable instructions further comprise:
receiving user input information indicating a selection of a staircase as an access structure option;
wherein the access structure selection module is further configured to perform operations including:
determining a staircase size;
wherein the staircase size depends upon the platform height value stored in the platform dimension data structure; and
wherein the footprint calculation module is further configured to determine total footprint area based upon the staircase size.

13. The system of claim 10,
wherein the computer executable instructions further comprise:
receiving a selection of a ladder as an access structure option;
wherein the access structure selection module is further configured to perform operations including:
determining a ladder size;
wherein the ladder size depends upon the platform height value stored in the platform dimension data structure; and
wherein the footprint calculation module is further configured to determine the total footprint area based upon the ladder size.

14. The system of claim 10,
wherein the computer executable instructions further comprise:
receiving a selection of required platform equipment; and
wherein the given elevated platform configuration is further selected based upon the required platform equipment selection.

15. The system of claim 10,
wherein the computer executable instructions further comprise:
receiving a selection of an equipment option priority; and
wherein the given elevated platform configuration is further selected based upon the equipment option priority.

16. The system of claim 10 further comprising:
a bill of materials module executable by the processor and configured to perform operations including:
generating a bill of materials;
wherein the bill of materials lists components for building the elevated structure according to the elevated platform specifications; and
outputting the bill of materials.

17. The system of claim 10,
wherein the access structure selection module is further configured to:
select a minimum standard platform configuration with an area greater than the minimum adequate elevated platform area;
geometrically arrange required equipment within the minimum standard platform configuration based on relevant equipment dimension data and relevant equipment clearance data for the required equipment;
determine whether the geometric arrangement of the required equipment fits within the minimum standard platform configuration;
if the required equipment does not fit,
iteratively geometrically rearrange the required equipment within the minimum standard platform configuration to determine whether any successive geometric rearrangement of the required equipment fits; and
if the required equipment fits,
select the minimum standard platform configuration as the given elevated platform configuration.

18. The system claim 17,
wherein the access structure selection module is further configured to:
select a next largest standard platform configuration if, after iterative geometrically rearrangement of the required equipment, no geometric rearrangement of the required equipment fits the minimum standard platform configuration.

19. A tangible processor-readable storage media embedded with non-transient computer instructions for executing a process on a computing device to determine optimal footprint dimensions for an elevated structure, the process comprising:
receiving user input information within the computing device indicating a platform height value of the elevated structure;
storing the platform height information in a platform dimension data structure;
determining a minimum adequate elevated platform area based, at least in part, upon equipment dimension data and equipment clearance data stored in a platform equipment data structure and elevated platform dimension options stored in the platform dimension data structure;
selecting a given elevated platform configuration based, at least in part, upon the determined minimum adequate elevated platform area;
determining and selecting an access structure size based, at least in part, upon the platform height value stored in the platform dimension data structure;
determining a total footprint area of the elevated structure based, at least in part, upon the selected elevated platform configuration and the selected access structure size; and
outputting elevated platform specifications to a user including the total footprint area.

20. The tangible processor-readable storage media of claim 19,
wherein the process further comprises:
initially selecting a minimum standard platform configuration with an area that is greater than the minimum adequate elevated platform area;
geometrically arranging required equipment within the minimum standard platform configuration based, at least in part, upon relevant equipment dimension data and relevant equipment clearance data for the required equipment from the platform equipment data structure;
determining whether the geometric arrangement of the required equipment fits within the minimum standard platform configuration; and one or more of the following:
if the required equipment does not fit, iteratively geometrically rearranging the required equipment within the minimum standard platform configuration to determine whether any successive geometric rearrangement of the required equipment fits; or
if the required equipment fits, selecting the minimum standard platform configuration as the given elevated platform configuration; or
if, after iteratively geometrically rearranging the required equipment, no geometric rearrangement of the required equipment fits the minimum standard platform configuration, selecting a next largest standard platform configuration.
